(19) United States
(12) Patent Application Publication
(10) Pub. No.: US 2024/0230247 A1
(43) Pub. Date: Jul. 11, 2024

(54) COOLING STRUCTURE, POWER MODULE COMPRISING SUCH A COOLING STRUCTURE, ELECTRICAL POWER CONVERTER, SUCH AS AN INVERTER, COMPRISING SUCH A POWER MODULE

(71) Applicant: Valeo eAutomotive Germany GmbH, Erlangen (DE)

(72) Inventors: Arnoud SMIT, Erlangen (DE); Michael HECHT, Erlangen (DE)

(73) Assignee: Valeo eAutomotive Germany GmbH, Erlangen (DE)

(21) Appl. No.: 18/558,668

(22) PCT Filed: May 24, 2022
(86) PCT No.: PCT/EP2022/063961

§ 371 Date: Nov. 2, 2023

(30) Foreign Application Priority Data
May 27, 2021 (DE) 10 2021 205 374.2

(51) Int. Cl. F28F 3/08; F28F 3/12; H05K 7/20

(52) U.S. Cl. CPC F28F 3/086; F28F 3/12; H05K 7/20936; H05K 7/20927

(57) ABSTRACT

A cooling structure including several layers and a network of local chambers distributed between the several layers stacked one on another according to a stacking direction. Each local chamber includes at least two apertures, of which at least one is in communication with a local chamber of another of the layers. Each local chamber includes one or several meander-like structures blocking any direct path in the local chamber between the two apertures.

The present invention relates to a cooling structure, a power module comprising such a cooling structure and an electrical power converter, such as an inverter, comprising such a power module. The invention is applicable in particular in an automotive vehicle.

Published European application No. EP 2 416 483 A2 describes a doubled sided single phase power module, which is directly cooled. In particular, the power module comprises a plate from which pins project. The pins are intended to be inserted into an opening of a flow path former so that a coolant flowing into the flow path former comes into contact with the pins.

An object of the invention is to improve the heat transfer between the cooling structure and the coolant.

The object of the invention is solved by means of a cooling structure comprising several layers and a network of local chambers distributed between the several layers stacked one on another according to a stacking direction, wherein each local chamber comprises at least two apertures, of which at least one is in communication with a local chamber of another of the layers, and wherein each local chamber comprises one or several meander-like structures blocking any direct path in the local chamber between the two apertures.

Thanks to the invention, in each local chamber, the coolant flowing between the two apertures is forced to get in contact with at least one meander-like structure, so that heat may be relatively easily transferred from wall of the meander-like structure to the coolant. This is in contrast with, for example, a triangular chamber where two apertures are located at respective vertices, in which a part of the coolant may follow a direct path between the two apertures without coming into contact with the walls of the chamber. In particular, each layer comprises one or more of the meander-like structures, in particular is formed by one or more of the meander-like structures.

Optional features of the invention will now be listed. These features may be carry out individually or in any combination.

In some embodiments, each meander-like structure has at least one curvature, i.e. a single one or a plurality of curves, around the stacking direction. Preferably, the curvatures are elliptic, circular, or double parabolic.

In some embodiments, each local chamber comprises several meander-like structures particular including at least a first curvature and at least a second curvature opposite to or different from the first curvature. Advantageously, the two curvatures with opposite curvatures relatively easily block any direct path between the two apertures. In particular, each layer comprises several meander-like structures particular including at least the first curvature and the at least one second curvature opposite to or different from the first curvature.

Preferably, the first and second curvatures are elliptic, circular, or double parabolic.

In some embodiments, the local chambers of each layer are separate one from another within their layer, so as to be connected one to another only through at least one local chamber of another layer. Advantageously, a flow of coolant towards different levels is achieved.

In some embodiments, two local chambers of two respective adjacent layers overlap each other, the overlap forming an aperture for both local chambers, these two local chambers having walls defining, in the overlap, two respective coolant flow directions forming with each other an angle comprised between 30° and 90°, preferably between 45° and 90°. Advantageously, the local chambers are, therefore, shaped to get impingement flows on the cross walls of the junction (overlap) of the local chambers. The impingement flow may improve the heat transfer considerably, so that heat is easily transferred from the chamber's wall to the coolant. In particular, the meander-like structures of two consecutive layers overlap each other, thus forming the aperture of the local chambers.

In some embodiments, the local chambers of each layer include identical local chambers. Advantageously, identical local chambers simplifies the design of the cooling structure.

In some embodiments, at least some local chambers of one layer are mirror images of at least some local chambers of an adjacent layer. Advantageously, mirror image chambers allows the coolant to drain more homogeneously heat from the cooling structure.

In some embodiments, the cooling structure comprises stacked plates respectively forming the layers, wherein each plate comprises holes respectively defining the local chambers of the corresponding layer. Advantageously, stacked plates offers an easy way to manufacture the network of local chambers.

The invention also relates to a power module comprising a main body, and a cooling structure according to the invention fixed to the main body. In particular, the main body comprises a base plate, wherein the cooling structure is fixed to the base plate.

Advantageously, the power module can then be easily mounted on a cooling channel having a cavity that was meant for a pin fin base plate. The layers would then extend in the cavity, instead of the pin fins.

In particular, the power module comprises controllable switches, for instance, controllable semiconductor switches, such as IGBTs. The power module is in particular configured to convert a DC voltage applied to an input of the power module into an AC voltage present at an output of the power module by controlling the controllable switches in a way known to the skilled person in the art.

The AC voltage may be a multiphase AC voltage, in particular a three phase voltage.

The power module may comprise two cooling structures according to the invention, particularly one fixed to one side of a main body of the power module and the other one fixed to an opposite side of the main body. Such power modules are sometimes known as double-sided cooled power modules.

The invention also relates to an electrical power converter comprising the power module or power modules and a cooling channel configured to at least indirectly cool the power module by means of its cooling structure. The electrical power inverter may be an inverter which is configured to convert a DC voltage into an AC voltage by means of the power module or power modules. The inverter my comprise a dc link capacitor to smooth the DC voltage applied to the inverter.

The power converter may configured such that the cooling channel comprises a cavity having an open side, wherein the cooling channel is fixed to the power module so that the side of the main body comprising the cooling structure, in particular the base plate, closes the open side and so that the cooling structure is received in the cavity. Then, a cooling liquid or fluid flowing through the cooling channel is in direct contact with the cooling structure, resulting in an improved cooling of the power module, in particular its controllable switches.

The invention also relates to an electric drive comprising an inverter according to the invention and an electric motor driven by the inverter.

The invention also relates to an automotive vehicle comprising an electric drive according to the invention, for example configured to drive at least one wheel of the automotive vehicle.

The present invention will be described more specifically with reference to the accompanying drawings, in which:

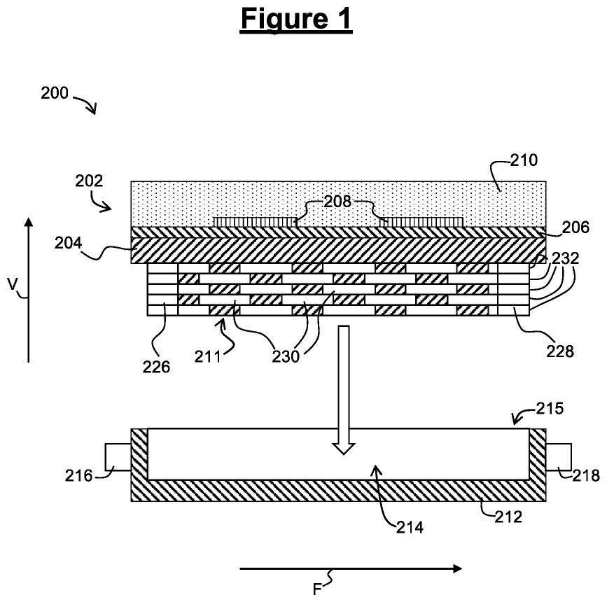

FIG. 1 is a cross-section view of an electrical power converter comprising a cooling structure according to the invention,

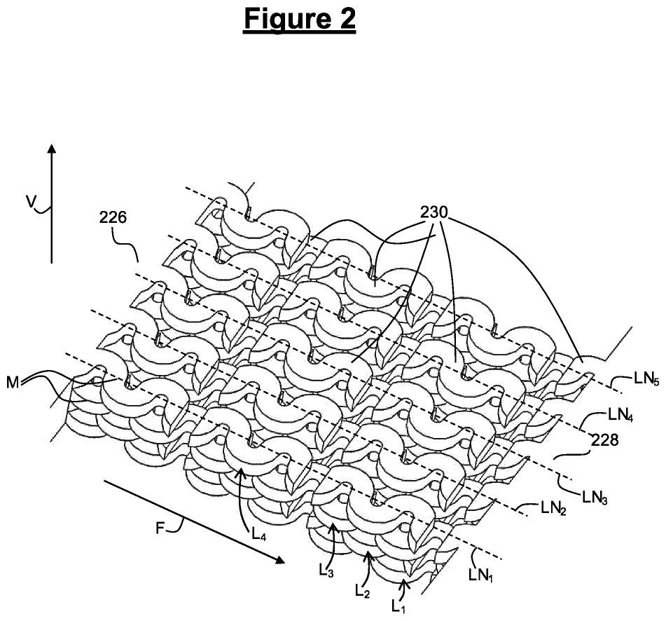

FIG. 2 is a three-dimensional view of a coolant flowing in a first example of network of chambers that may be used in the cooling structure of FIG. 1,

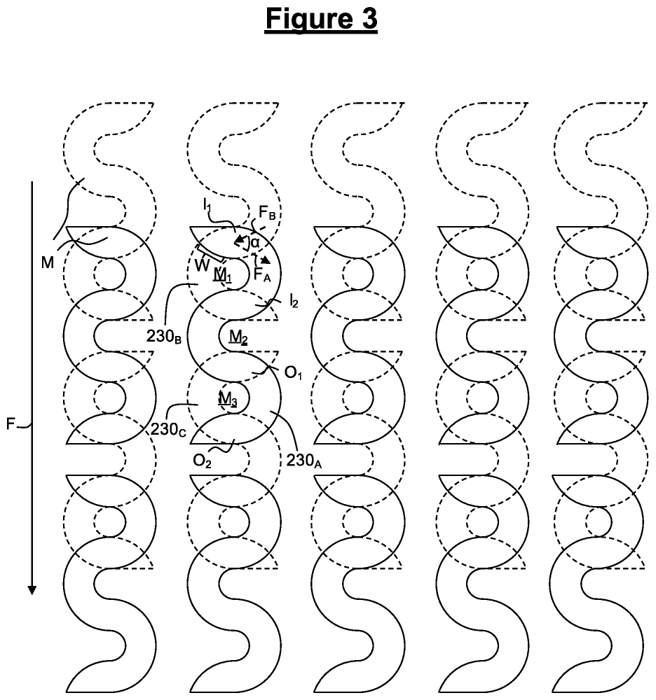

FIG. 3 is a top view of the coolant in some of the chambers of FIG. 2,

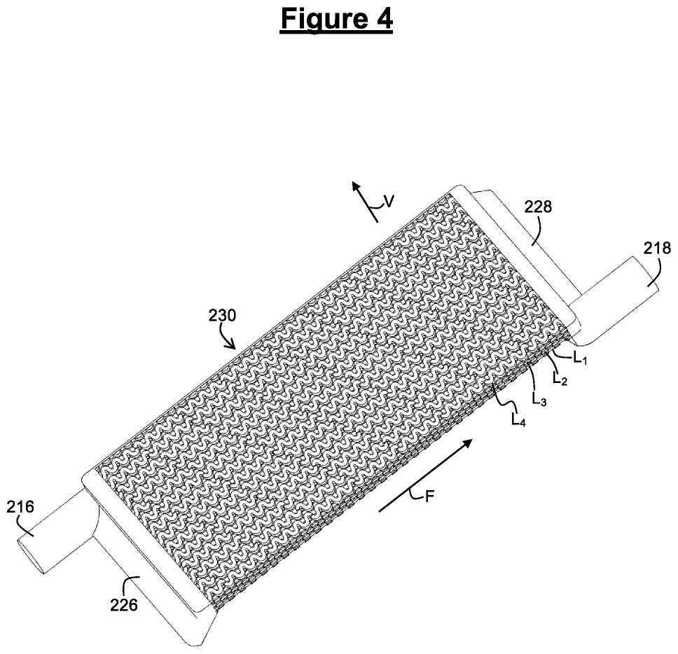

FIG. 4 is a three-dimensional view of a coolant flowing in a second example of network of chambers that may be used in the cooling structure of FIG. 1,

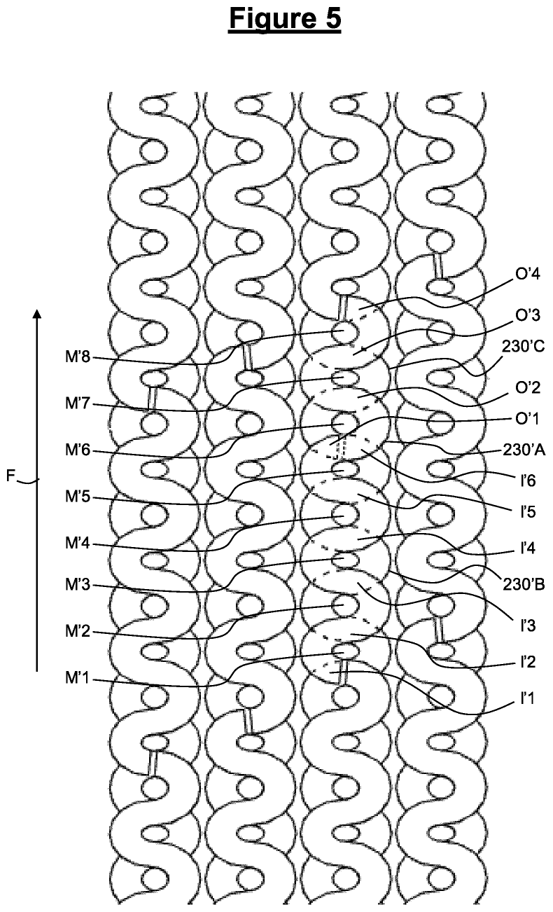

FIG. 5 is a top view of the coolant in some of the chambers of FIG. 4,

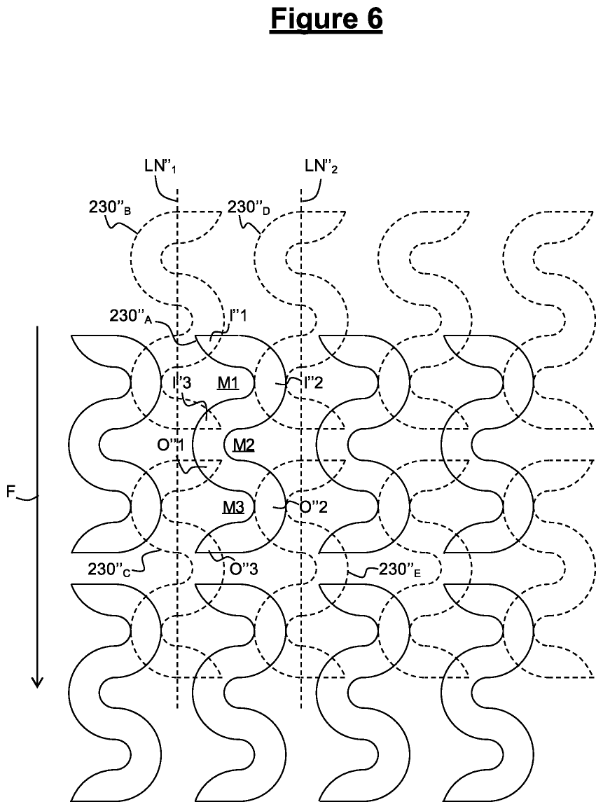

FIG. 6 is a top view of the coolant in some of the chambers of a third example of network of chambers that may be used in the cooling structure of FIG. 1, and

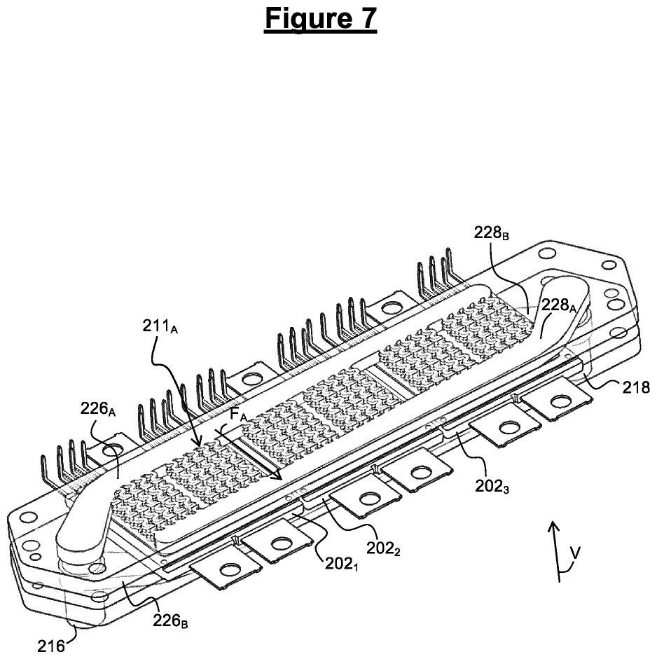

FIG. 7 is a three-dimensional view of three power modules with a common cooling structure according to the invention, with a transparent housing to see the coolant, and

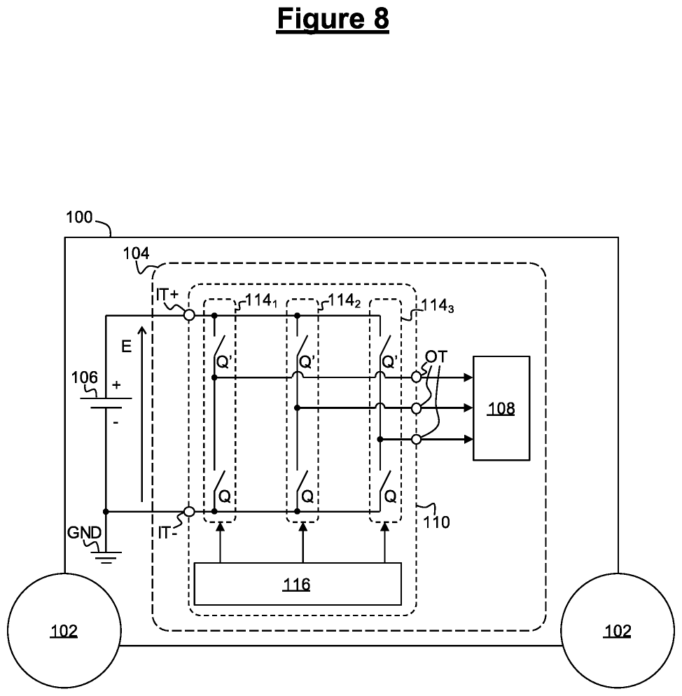

FIG. 8 is a simplified view of an automotive vehicle comprising an inverter where a cooling structure according to the invention may be used.

Referring to FIG. 1, an example of an electrical power converter 200 in which the invention is carried out will now be described. The power converter may be an inverter configured to convert a DC voltage into an AC voltage. The inverter may comprise a DC link capacitor configured to smooth the DC voltage.

The following description will be made with reference to an arbitrary direction V taken, for instance, as the vertical direction.

The electrical power converter 200 comprises a power module 202 in particular to perform the conversion of the DC voltage into the AC voltage.

The power module 202 comprises a main body including a base plate 204 and a substrate 206 fixed on a top face of the base plate 204. The substrate 206 is, for example, a Direct Bonded Copper (DBC) substrate comprising, for instance, a ceramic plate with copper layers on both sides. The substrate 206 can, for example, also be lead frame on top of an isolation layer that is somehow connected to the base plate 204. The power module 202 further comprises controllable switches, for instance, semi-conductor power components 208 supported by the substrate 206.

The power module 202, specifically its main body comprises an electrically insulating housing 210 surrounding the substrate 206 and the semi-conductor power components 208, while letting apparent at least a part of a downward face of the base plate 204. The electrically insulating housing 210 may comprise for example epoxy resin or alternatively a plastic casing filled up with an electrically insulating gel.

The power module 202 further comprises a cooling structure 211 fixed to the main body, in particular to a bottom face of the base plate 204.

The electrical power converter 200 further comprises a cooling channel 212 for cooling the power module 202, specifically its controllable switches. The cooling channel 212 is configured to guide a coolant, for instance, a cooling liquid or a cooling fluid. The coolant may be a liquid such as water or even a liquid-gas mixture such as a two phase refrigerant (as for instance in air conditioning circuits or heat pumps). The cooling channel 212 comprises a cavity 214 with an open top side 215 and a general coolant inlet 216 for letting coolant enter the cavity 214 and a general coolant outlet 218 for letting coolant leaving the cavity 214.

The cooling channel 212 is configured to be fixed to the power module 202, for example, to the base plate 204 so that the base plate 204 of the power module 202 closes the open top side 215 and so that the cooling structure 211 is received in the cavity 214, where the cooling structure 211 and the cooling channel 212 are fixed to each other. This fixation may comprise a sealing.

The cooling structure 211 will now be described in greater detail.

The cooling structure 211 comprises a network of chambers 230 provided, as it will be explained below in greater detail, with meander-like structures.

In the described example, the cooling structure 211 defines a general inlet chamber 226 connected to the general coolant inlet 216 and a general outlet chamber 228 connected to the general coolant outlet 218. In this manner, the coolant is intended to cross the chambers 230 according to a general or main direction of flow F in particular perpendicular to the vertical direction V in the described example, for flowing from the general inlet chamber 226 to the general outlet chamber 228.

As illustrated, the chambers 230 are distributed between several layers, stacked one on another according to the vertical direction V. In particular, each layer comprises one or more meander-like structures M, in particular is formed by one or more of the meander-like structures M.

For example, the layers are respectively formed by plates 232 in which holes are provided. The plates 232 are stacked one on another according to the vertical direction V. Each hole is partially closed from below by the previous plate in the stack, or by the cooling channel 212 for the lowest plate 232, and from above by the next plate in the stack, or by the base plate 204 of the power module 202 for the highest plate 232, so that the holes respectively form the chambers 230. For example, the holes are obtained by etching, water or laser jet cut and stamping, etc. The plates 232 may be bonded together, for example, by cold rolling and/or soldering or brazing or gluing.

Advantageously, the power module 202 could easily be mounted on a cooling channel having a cavity that was meant for a pin fin cooling structure, i.e. pin fins projecting downwards from the base plate 204. The cooling structure 211 would then extend in the cavity, instead of the pin fins.

The cooling channel 212 can be a separate part, as illustrated in FIG. 1 but can also be integrated in the structure of the plates 232 where the plates 232 themselves form outer wall defining the cooling channel, without the need of separate walls (which finally leads to the configuration of FIG. 7).

Referring to FIG. 2, an example of a network of chambers 230 of the cooling structure 211 will now be described in greater detail. FIG. 2 is a three-dimensional view of a coolant flowing in a first example of network of chambers that may be used in the cooling structure of FIG. 1.

In the illustrated example, the chambers 230 are distributed between four layers L₁, L₂, L₃, L₄ stacked in the vertical direction V.

The chambers 230 of each layer L₁₋₄ are aligned on lines (five for each layer L₁₋₄ in the illustrated example, referenced by LN₁, LN₂, LN₃, LN₄, LN₅) parallel to the general direction of the general or main flow F. In the described example, each line LN₁₋₅ comprises identical chambers (two in the described example) and, for example, two truncated chambers at the two extremities of the line LN₁₋₅, around the complete chambers, for adjusting the cooling structure 211 to the distance between the general inlet chamber 226 and the general outlet chamber 228. The truncated chambers are for example identical to the complete chambers except that they are truncated.

The chambers 230 of each layer L₁₋₄ are separated within their layer so that, for flowing between two consecutive chambers 230 of a line LN₁₋₅, the coolant has to pass through at least one chamber 230 of another layer L₁₋₄. In order to allow the flow of coolant between chambers 230 of different layers L₁₋₄, each chamber 230 overlaps with chambers 230 of an adjacent layer L₁₋₄ (higher layer and/or lower layer). Preferably, two consecutive chambers 230 in a line LN₁₋₅ both overlap with the same chamber 230 of an adjacent layer L₁₋₄. The overlap between two chambers 230 of adjacent layers forms a coolant aperture allowing coolant communication between these two chambers. The aperture therefore forms a local coolant inlet for one of the chambers 230 and a local coolant outlet for the other of the chambers.

Furthermore, the truncated chambers 230 at the extremities of each line LN₁₋₅ comprises a local inlet with the general inlet chamber 226 or a local outlet with the outlet chamber 228. In this manner, each chamber 230 comprises at least one pair of coolant apertures (one local inlet and one local outlet).

Each complete chamber 230 has the shape of a tube (with a rectangular cross section in the described example) comprising at least one meander-like structure M along the direction of the general or main flow F. In the described example, each complete chamber 230 comprises three successive meander-like structures: two meander-like structures with a first curvature M₁, M₃; M′₁, M′₃, M′₅, M′₇, around the vertical direction V and, between them, a further meander-like structure with a second curvature M′₂, M′₄, M′₆, M′₈ around the vertical direction V, inverse to the first curvature.

In the described example, the complete chambers 230 of one layer L₁₋₄ are vertically mirror images of the complete chambers 230 of the next layer L₁₋₄ (i.e. with respect to a plane parallel to the vertical direction V and the flow direction F).

The complete chambers 230 of two consecutive layers L₁₋₄ are illustrated in FIG. 3, from above, respectively in plain line and in dashed line. The complete chamber 230_{A} overlaps with aligned chambers 230_{B} and 230_{C} of the other adjacent layer. For chamber 230_{A}, the overlaps forming local inlets from the chamber 230_{B} are referenced I₁, I₂ and the overlaps forming local outlets to the chamber 230_{C} are referenced O₁, O₂.

As can be seen, the curvatures M₁₋₂ block any direct flow path (i.e. a path in a straight line) from the local inlet I₁ to the local outlet O₁. The curvatures M₁₋₃ block any direct flow path from the local inlet I₁ to the local outlet O₂. The curvatures M₂₋₃ block any direct flow path from the local inlet I₂ to the local outlet O₂. In this manner, coolant flowing from the local inlet I₁ to the local outlet O₁, from the local inlet 11 to the local outlet O₂ and from the local inlet I₂ to the local outlet O₂ is forced to come into contact with at least some of the meander-like structures, in particular with its curvatures M₁₋₃ which increases heat transfer between the cooling structure 211 and the coolant.

Two chambers, for example, chambers 230_{A} and 230_{B}, of two respective adjacent layers overlap each other, the overlap forming an aperture (for example, the aperture I₁) for both chambers. The two chambers have preferably walls defining, in the overlap (i.e. in the aperture I₁), two respective coolant flow directions (arrows F_{A} and F_{B}) forming with each other an angle α comprised between 30° and 90°, preferably between 45° and 90°. In this manner, impingement flow can be obtained. For instance, the coolant coming from the chamber 230_{B} will at least partially hit the wall W of the chamber 230_{A} with the angle α, when entering the chamber 230_{A} through the aperture I₁. The wall W therefore forms an impingement wall.

Another example of arrangement of the chambers 230 is illustrated in FIG. 4. In this example, each complete chamber 230 comprises a total of seven meander-like structures and overlaps with two consecutive aligned chambers 230 of the lower and/or higher adjacent layer L₁₋₄.

Referring to FIG. 5, one of the complete chambers of FIG. 4, referenced 230′_{A}, will now be described in detail.

The complete chamber 230′_{A} comprises, for instance, meander-like structures having four curvatures M′₁, M′₃, M′₅, M′₇, with a first curvature around the vertical direction V and, in between them, meander-like structures M having four curvatures M′₂, M′₄, M′₆, M′₈ with the opposite curvature around the vertical direction V. The complete chamber 230′_{A} overlaps with the two consecutive aligned chambers 230′B, 230′_{C} of the lower or upper adjacent layer. This overlapping defines, in the chamber 230′_{A}, six local inlets I′₁, I′₂, I′₃, I′₄, I′₅, I′₆ from the chamber 230′_{B} and four local outlet O′₁, O′₂, O′₃, O′₄ to the chamber 230′_{C}.

As illustrated, any direct path from any of the local inlet I′₁₋₆ to any of the local outlets O′₁₋₄ is blocked by at least some of the meanders M′₁₋₈, except for the local inlet I's and the local outlet O′₁ for which direct paths exist.

Referring to FIG. 6, another example of network of chambers 230 will now be described. On FIG. 6, only the complete chambers are illustrated.

The complete chambers 230 are identical to those of FIG. 3, in particular they comprise the three meanders M₁₋₃. However, they are arranged differently so that each complete chamber 230 overlap not only with two consecutive chambers (on a same line) of an adjacent layer, but also with at least one chamber of this adjacent layer located on an adjacent line.

For example, the complete chamber 230″_{A} overlaps with the chambers 230″_{B}, 230″_{C}, 230″_{D}, 230″_{E} of the adjacent layer, including the aligned consecutive chambers 230″_{B} and 230″C of the first line LN″₁ and the two aligned consecutive chambers 230″_{D} and 230″_{E} of the line LN″₂, adjacent to the first line LN″₁.

In this manner, in the described example, the chamber 230″_{A} comprises two local inlets I″₁, I″₃ from the chamber 230″_{B} and one local inlet I″₂ from the chamber 230″_{D}, as well as two local outlets O″₁, O″₃ to the chamber 230″_{C} and one local outlet O″₂ to the chamber 230″_{E}.

As can be seen, at least some of the curvatures M₁₋₃ block any direct path between any of the local inlet I″₁₋₃ to any of the local outlet O″₁₋₃, except for the local inlet I″₃ and the local outlet O″₁ for which direct paths exist.

Referring to FIG. 7, in some embodiments, a common cooling structure 211_{A} according to the invention could be used to cool several power modules 202₁, 202₂, 202₃. On FIG. 7, the cooling structure 211_{A} cools the power modules 202₁₋₃ from above, according to the direction of flow F_{A}. The chambers of the cooling structure 211_{A} could be arranged according to any of the arrangements described above, or any other arrangement. The chambers of the cooling structure 211_{A} extend from the general inlet chamber 226_{A} to the general outlet chamber 228_{A}, respectively connected to the general coolant inlet 216 and the general coolant outlet 218 of the cooling channel 212.

Besides, two cooling channels in which two respective cooling structures could be provided, located on opposite sides of the power module(s) for a double side cooling. The two cooling structures could be connected to the same coolant inlet and coolant outlet. For example, on FIG. 7, another cooling structure (not visible), similar to the cooling structure 211_{A}, is provided to cool the power modules 202₁₋₃ from below. Preferably, the respective directions of flow for the two cooling structures are opposite one form another. In the described example, the chambers of the below cooling structure extend from the general inlet chamber 226_{B} to the general outlet chamber 228_{B}, respectively connected to the general coolant inlet 216 and the general coolant outlet 218.

Referring to FIG. 8, an example of vehicle 100 in which the invention may be carried out will now be described. In the described example, the vehicle 100 is an automotive vehicle.

The vehicle 100 comprises wheels 102 for moving the vehicle 100 by friction on the ground (e.g. a road) and an electric drive 104 configured to drive at least one of the wheels 102 at least indirectly. The vehicle 100 further comprises a DC voltage source 106, such as a battery, for electrically powering the electric drive 104. The DC voltage source 106 is configured to provide a DC voltage E.

The electric drive 104 comprises an electric motor 108 and an inverter 110 configured to drive the electric motor 108, for instance by supplying electric power. For example, the electric motor 108 is a rotary electric motor comprising stator phases. In the described example, the electric motor 108 is a three-phase electric motor comprising three stator phases.

The inverter 110 comprises input terminals IT+, IT− connected to the DC voltage source 106 so that the DC voltage E is present at the input terminals IT+, IT−. More precisely, the input terminals IT+, IT− include a positive input terminal IT+ connected to a positive terminal of the DC voltage source 106 and a negative input terminal IT− connected to a negative terminal of the DC voltage source 106 and to an electrical ground GND.

The inverter 110 further comprises output terminals OT connected to the electric motor 108. An AC voltage is intended to be present at the output terminals OT for powering the electric motor 108. The AC voltage may be a single or a multiphase AC voltage. In the described example where the electric motor 108 is a three-phase electric motor, the AC voltage is a three-phase AC voltage.

The inverter 110 further comprises controllable switches Q, Q′, called main switches, connected to the input terminals IT+, IT− and to the output terminals OT. The main switches Q, Q′ are semi-conductor switches comprising for example transistors. Each main switch Q, Q′ comprises for example one amongst: a Metal Oxide Semiconductor Field Effect Transistor (MOSFET), an Insulated Gate Bipolar Transistor (IGBT) and a Silicon Carbide MOSFET (SiC MOSFET). These switches Q, Q′ correspond for example to the semi-conductor power components 208 of FIG. 1.

In the described example, the inverter 110 comprises switch legs 114₁₋₃ respectively associated to the stator phases of the electric motor 108. Each switch leg 114₁₋₃ comprises a high side (HS) main switch Q′ connected to the positive input terminal IT+ and a low side (LS) main switch Q connected to the negative input terminal IT−. The HS main switch Q′ and the LS main switch Q are connected to each other at a middle point connected to the output terminal OT connected to the associated stator phase of the electric motor 108.

Each switch leg 114₁₋₃ is intended to be controlled to commute between two configurations. In the first one, called high side (HS) configuration, the HS main switch Q′ is closed (on) and the LS main switch Q is open (off) so that the DC voltage E is essentially applied to the associated stator phase. In the second one, called low side (LS) configuration, the HS main switch Q′ is open (off) and the LS main switch Q is closed (on) so that a zero voltage is essentially applied to the associated stator phase.

The inverter 110 further comprises a control device 116 configured to control the main switches Q, Q′ such that the main switches Q, Q′ convert the DC voltage E into the AC voltage. In the described example, the control device 116 is configured to commute each switch leg 114 between the two configurations mentioned above.

The power module 202 could implement, for example, one of the switch leg 114₁₋₃ or all the switch legs 114₁₋₃.

It will be noted that the invention is not limited to the embodiments described above. It will indeed appear to those skilled in the art that various modifications can be made to the embodiments described above, in the light of the teaching which has just been disclosed.

In particular, the layers may be different (e.g. the shape of the chambers of one layer is different from the shape of the chambers of another layer). Furthermore, the curvatures can by asymmetric, for example have different curvature. A meander could also be obtained with a “V” shape, i.e. with two plane walls joining each other at a certain angle.

In the previous detailed description of the invention, the terms used should not be interpreted as limiting the invention to the embodiments presented in the present description, but should be interpreted to include all the equivalents within the reach of those skilled in the art by applying their general knowledge to the implementation of the teaching which has just been disclosed.

1. Cooling structure comprising several layers (L1-4) and a network of local chambers distributed between the several layers (L1-4) stacked one on another according to a stacking direction, wherein each local chamber comprises at least two apertures, of which at least one is in communication with a local chamber of another of the layers, and wherein each local chamber comprises one or several meander-like structures blocking any direct path in the local chamber between the two apertures.

2. Cooling structure according to claim 1, wherein each meander-like structure has a curvature around the stacking direction, and or each.

3. Cooling structure according to claim 1, wherein each meander-like structure includes a first curvature and a second curvature, opposite to or different from the first curvature.

4. Cooling structure according to claim 1, wherein the local chambers of each layer (L1-4) are separate one from another within their layer (L1-4), so as to be connected one to another only through at least one local chamber of another layer.

5. Cooling structure according to claim 1, wherein the local chambers of each layer (L1-4) include identical local chambers, or are essentially identical.

6. Cooling structure according to claim 1, wherein at least some local chambers of one layer (L1-4) are mirror images of at least some local chambers of an adjacent layer (L1-4).

7. Cooling structure according to claim 1, comprising stacked plates respectively forming the layers (L1-4), wherein each plate comprises holes respectively defining the local chambers of the corresponding layer (L1-4).

8. Power module, comprising:
a main body, and
a cooling structure according to claim 1, fixed to the main body.

9. Electrical power converter, in particular inverter, comprising:
a power module according to claim 8, and
a cooling channel configured to at least indirectly cool the power module by means of its cooling structure.

10. Electrical power converter according to claim 9, wherein the cooling channel comprises a cavity having an open side, wherein the cooling channel is fixed to the power module so that the side of the main body comprising the cooling structure closes the open side and so that the cooling structure is received in the cavity.

11. Cooling structure according to claim 2, wherein each meander-like structure includes a first curvature and a second curvature, opposite to or different from the first curvature.

12. Cooling structure according to claim 2, wherein the local chambers of each layer (L1-4) are separate one from another within their layer (L1-4), so as to be connected one to another only through at least one local chamber of another layer.

13. Cooling structure according to claim 2, wherein the local chambers of each layer (L1-4) include identical local chambers, or are essentially identical.

14. Cooling structure according to claim 2, wherein at least some local chambers of one layer (L1-4) are mirror images of at least some local chambers of an adjacent layer (L1-4).

15. Cooling structure according to claim 2, comprising stacked plates respectively forming the layers (L1-4), wherein each plate comprises holes respectively defining the local chambers of the corresponding layer (L1-4).

16. Power module, comprising:
a main body, and
a cooling structure according to claim 2, fixed to the main body.

17. Cooling structure according to claim 3, wherein the local chambers of each layer (L1-4) are separate one from another within their layer (L1-4), so as to be connected one to another only through at least one local chamber of another layer.

18. Cooling structure according to claim 3, wherein the local chambers of each layer (L1-4) include identical local chambers, or are essentially identical.

19. Cooling structure according to claim 3, wherein at least some local chambers of one layer (L1-4) are mirror images of at least some local chambers of an adjacent layer (L1-4).

20. Cooling structure according to claim 3, comprising stacked plates respectively forming the layers (L1-4), wherein each plate comprises holes respectively defining the local chambers of the corresponding layer (L1-4).
